(19) United States
(12) Patent Application Publication
(10) Pub. No.: US 2009/0078940 A1
(43) Pub. Date: Mar. 26, 2009

(54) Location-controlled crystal seeding

(75) Inventors: Themistokles Afentakis, Vancouver, WA (US); Robert S. Sposili, Vancouver, WA (US); Apostolos T. Voutsas, Portland, OR (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/904,133

(22) Filed: Sep. 26, 2007

(51) Int. Cl. H01L 29/04; H01L 21/84

(52) U.S. Cl. 257/64; 438/166; 257/E29.003; 257/E21.7

(57) ABSTRACT

A structure with location-controlled crystallization of an active semiconductor film using a crystal seed has been provided, along with an associated fabrication method. The method forms a first semiconductor film overlying a substrate having a crystallographic orientation. Typically, the structure is polycrystalline or single-crystal. The first semiconductor film is selectively etched, forming a seed region. An insulator is formed with an opening, exposing the seed region. An amorphous second semiconductor film is formed over the insulator layer. The second semiconductor film is laser annealed, partially melting the seed region. Crystal grains are laterally grown in the second semiconductor film having the same crystallographic orientation as the seed region. In TFT fabrication an etching is typically performed to remove the second semiconductor film overlying the seed region, and a transistor active region is formed in the remaining second semiconductor film.

### 1. FIELD OF THE INVENTION

This invention generally relates to integrated circuit (IC) fabrication and, more particularly, to a transistor polycrystalline active layer, annealed using a location-controlled seed region.

### 2. DESCRIPTION OF THE RELATED ART

Polycrystalline silicon films produced by laser crystallization typically have an effectively random distribution of crystallographic orientations among the numerous grains comprising the film. Given the typical grain sizes of such films, there are many high-angle grain boundaries that ultimately fall within the active channel of any TFT devices fabricated in the films. The presence of such grain boundaries within the active channel portion of a TFT device is known to have strong detrimental effects on the device performance. Many approaches have been explored for reducing or eliminating the grain boundaries from the active channel regions. For example, increasing the grain size reduces the density of grain boundaries, and thus reduces the average number of grain boundaries that will fall within the active channel of a device. If the grain size can be made larger than the active channel region, the average number of grain boundaries that fall within the channel will be less than one. However, even if the grain size is larger than the channel size, but the placement of grain boundaries is random, there is still a probability that some active channels with contain one or more grain boundaries.

Furthermore, even if the grain-to-channel size ratio is high, there is a high probability that devices, adjacent to a device with a grain boundary in the channel, will include channels with no grain boundaries. This situation leads to large non-uniformities in the performance of adjacent thin-film transistor (TFT) devices. Those devices with no grain boundaries in the channel have a relatively high performance and those with a grain boundary (or two) have a lower performance.

While relatively high energy densities are typically needed to form a polycrystalline structure, many substrate materials are temperature sensitive, making for complicated annealing processes. For hybrid continuous grain silicon (CGS) processing of silicon (Si) thin-films for TFT applications, the “1-shot” process is a high-throughput scheme that can provide location control of the grain boundaries in the crystalline film. A laser pulse is typical referred to as a “shot”, and a 1-shot process uses a single laser pulse to anneal a film. There are two main implementations of this approach that affect the resulting microstructure—either pre-patterning the Si islands prior to crystallization, or not. In either case, the location control is induced by fully melting the Si film in all areas except where a pre-positioned seed is desired, to begin the crystallization of the supercooled melt. Typically, this seed is placed by first encapsulating the Si layer (either pre-patterned or non-patterned) with a 500 Å SiO₂ cap layer, and then patterning the Si layer to leave behind dots or lines that will shadow the excimer laser radiation from the underlying Si active layer. The dots or lines have to be large enough to keep a sufficiently wide region of the Si underlayer from being irradiated, in order to account for lateral heat diffusion. Typical widths are on the order of 3-4 microns (μm). When the surrounding molten Si begins to cool below the equilibrium temperature, the seed initiates lateral growth into the surrounding regions.

FIG. 1 is a perspective drawing depicting a pre-patterned Si active layer with a shadow Si layer (dot) for a “1-shot” location control crystallization scheme (prior art). FIG. 1 shows a 70° tilted sample with a pre-patterned Si island and a cap Si layer to induce lateral growth. Upon irradiation, the seed initiates growth from under the shadow dot and lateral growth then proceeds around the spiral and into the remainder of the Si island.

In many embodiments of the above-described approach, the dot must eventually be removed, which can be problematic for subsequent TFT fabrication steps (e.g., implantation, contact hole formation, and planarity). Removal of the dot requires either a controlled dry etch of the Si shadow layer, a wet etch in TMAH, or (for non-patterned Si active layers) an etch in dilute HF to undercut the lines and dots and cause them to lift off.

A better approach would be to seed the lateral growth via a means that can be left in place following the crystallization and that will not interfere with subsequent processing steps.

It would be advantageous if, in addition to making the crystal grains large with respect to active channel of a transistor device, the location of the grain boundaries could be controlled, to ensure that the grain boundaries are always outside of the active channel. In this manner, all devices would have a uniformly high performance.

### SUMMARY OF THE INVENTION

Based upon a study of the efficacy of seed placement relative to the location of an active channel, an optimized geometry for location-controlled laser crystallization has been developed. Described within is a method that patterns an underlying film, adds an insulating layer, and forms an opening through to the patterned layer to seed location-control the crystallization of an overlying film. For example, a “1-shot” location control crystallization scheme can be enhanced if a predetermined region of the Si active layer can be left in contact with an area of solid (i.e., non-melted) Si that can act as a seed for lateral growth.

Accordingly, a method is provided for the location-controlled crystallization of an active semiconductor film using a crystal seed. The method forms a first semiconductor film overlying a substrate having a crystallographic orientation and a crystalline structure. Typically, the structure is polycrystalline or single-crystal. The first semiconductor film is selectively etched, forming a seed region. An insulator is formed over the seed region and an opening in the insulator, exposing the seed region. A second semiconductor film, typically in an amorphous or polycrystalline state, is formed over the insulator layer. The second semiconductor film is laser annealed, which completely melts the second semiconductor film and partially melts the seed region. Crystal grains are laterally grown in the second semiconductor film having the same crystallographic orientation as the seed region. In TFT fabrication an etching is typically performed to remove the second semiconductor film overlying the seed region, and a transistor active region is formed in the remaining second semiconductor film.

The method can be used to fabricate top gate TFTs, where the gate electrode is formed over the above-mentioned active region. In another aspect, the first semiconductor film can be selectively etched to form a bottom gate overlying the substrate, adjacent to the seed region. In a third aspect, the TFT may have both a bottom gate and a top gate.

Additional details of the above-described method and an active semiconductor film structure formed from location-controlled crystallization of a crystal seed are provided below.

### BRIEF DESCRIPTION OF THE DRAWINGS

FIG. 1 is a perspective drawing depicting a pre-patterned Si active layer with a shadow Si layer (dot) for a “1-shot” location control crystallization scheme (prior art).

FIG. 2 is a partial cross-sectional view of an active semiconductor film structure formed from location-controlled crystallization of a crystal seed.

FIG. 3 is a perspective drawing depicting an exemplary orientation axis of the seed film used to form the seed region of FIG. 1.

FIG. 4 is a partial cross-sectional view of the structure of FIG. 2, depicting the seed region and opening in greater detail.

FIG. 5 is a plan view of the structure of FIG. 1.

FIG. 6 is a partial cross-sectional view depicting a variation in the structure of FIG. 2.

FIGS. 7A through 7D depict steps in a process of forming relatively large crystal grains with controlled boundary locations using an underlying seed region.

FIGS. 8A through 8F are steps in the process of fabricating a TFT with a top gate and a bottom gate, using a location-controlled crystal seeding process.

FIGS. 9A and 9B are graphs depicting the average mobility in devices made using the location-controlled crystal seeding process.

FIG. 10 is a graph depicting the mean effective mobility of TFTs, contrasting a CW-crystallized seed with an amorphous seed.

FIG. 11 is a flowchart illustrating a method for location-controlled crystallization of an active semiconductor film using a crystal seed.

### DETAILED DESCRIPTION

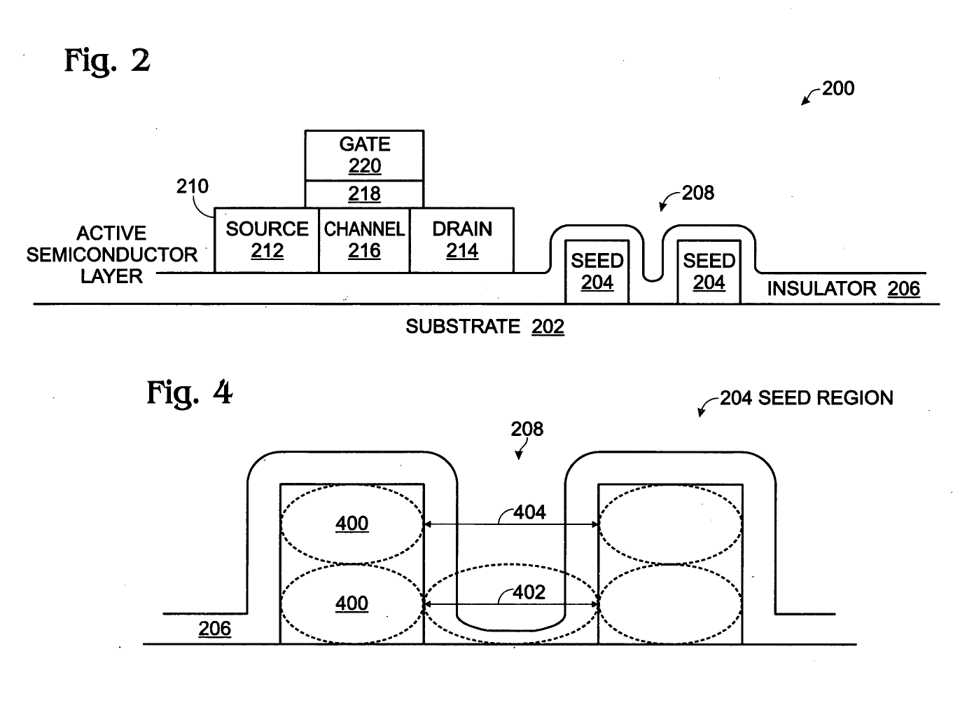

FIG. 2 is a partial cross-sectional view of an active semiconductor film structure formed from location-controlled crystallization of a crystal seed. The structure 200 comprises a substrate 202 and a seed region 204 formed overlying the substrate 202, having a crystallographic orientation and a crystalline structure. Typically, the crystalline structure is either polycrystalline or single-crystal. An insulator 206 overlies the seed region 204. An opening 208 in the insulator 206 exposes the seed region 204. An active semiconductor layer 210 overlies the insulator layer 206, adjacent the opening 208, having the same crystallographic orientation as the seed region 204. Alternately but not shown, the opening 208 (and seed region 204) may directly underlie the active semiconductor layer 210. However, it is typically advantageous for good electrical characteristics that the active semiconductor region be isolated from the seed region 204. Although the opening is shown as lined with the insulator 206, in other aspects not shown, the opening may be filled with remnants of the film used to form the active semiconductor layer, or filled with another insulator. In other aspects not shown, the seed region is larger, completely underlying the active semiconductor layer, or several adjacent active semiconductor layers.

The seed region 204 and active semiconductor layer 210 may be made from materials such as Si, Si-Germanium (SiGe), Ge, or a silicon-containing material. The substrate 202 may be a material such as glass, plastic, quartz, fused silica, silicon, and silicon-on-insulator (SOI). However, the structure is not limited to any particular material.

A source 212, drain 214, and channel 216 are formed in the active semiconductor layer 210. As shown, a top gate dielectric 218 overlies the active semiconductor layer 210, and a top gate (electrode) 220 overlies the top gate dielectric 218.

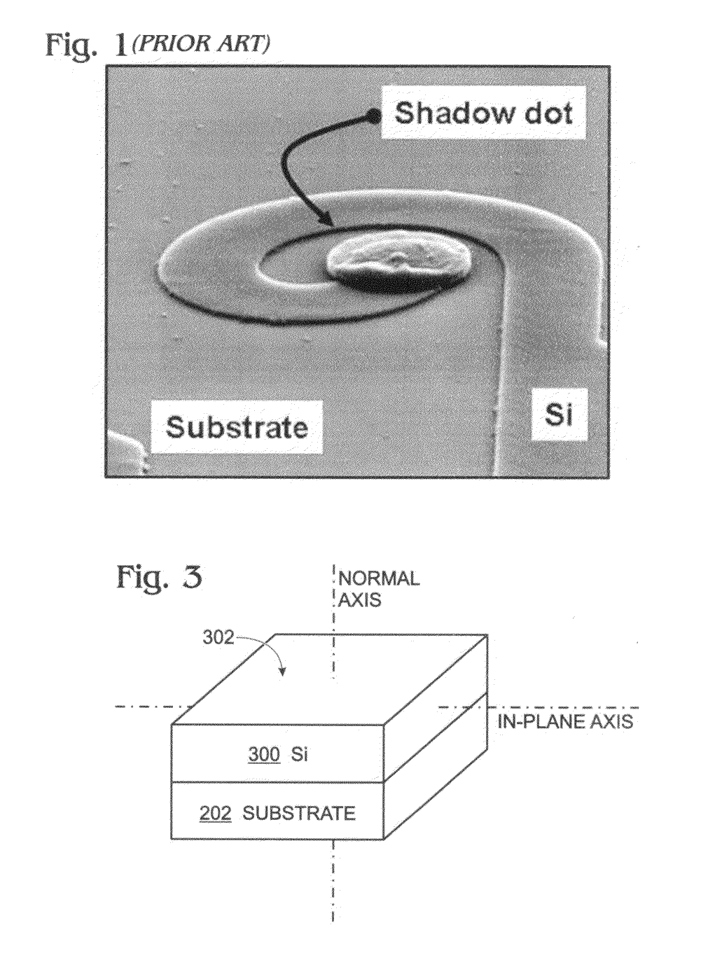

FIG. 3 is a perspective drawing depicting an exemplary orientation axis of the seed film used to form the seed region of FIG. 1. Considering both FIGS. 2 and 3, in one aspect the seed region 204 has a dominant (100) crystallographic orientation normal with respect to a seed region top surface 302. For example, the seed film 300 may be polycrystalline Si, with a small average grain size, in the region of 1 micrometer (um). The majority of the crystals, typically >90%, have a (100) orientation normal to the surface, while their in-plane orientation appears random.

The advantage of using a seeding process to form the active semiconductor layer is that the process can generate larger grains of the preferred (100) orientation, from a starting material that is (100) to begin with, but with a much smaller grain size. Ideally, the TFT channel is positioned in such a way with respect to the “seed”, so that a single grain will form the channel. That is, no grain boundaries are formed in the channel.

FIG. 4 is a partial cross-sectional view of the structure of FIG. 2, depicting the seed region 204 and opening 208 in greater detail. The seed region 204 includes crystal grains 400 (in phantom) with an average grain size 402. For simplicity, it is assumed that the grains are essentially circular or oval, and that the grain size 402 can be defined by a diameter. In practice however, the grains need not necessarily have uniform shapes. The opening 208 in the insulator 206 has a diameter 404 about equal to the average grain size 402.

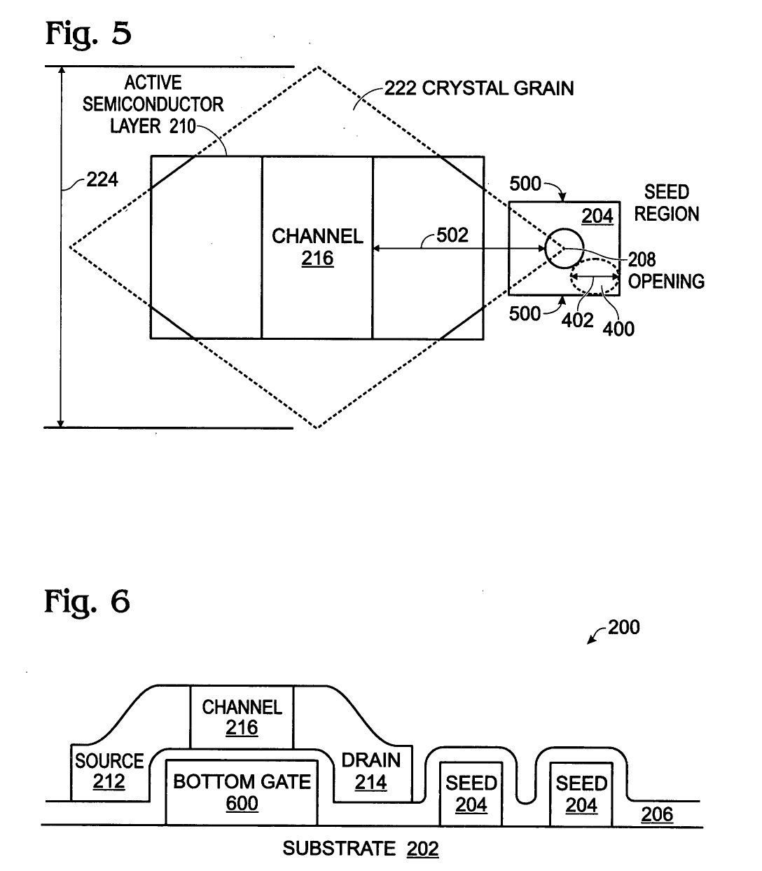

FIG. 5 is a plan view of the structure of FIG. 1. In one aspect, the active semiconductor layer includes crystal grains 222 having an average crystal grain diameter 224 of about 10 micrometers or greater. The lines in phantom represent that part of the crystal etched away when the active semiconductor layer is formed. Again, it is assumed that the shape of the grains 222 is essentially circular or oval, although the “tops” and “bottoms” of the grains (not shown) would be planar along the top (gate dielectric interface) and bottom (substrate interface) surfaces. The seed region 204 typically has a shape that is diamond or rectangular (a square is shown), with sides 500 in the range of 2 to 5 micrometers. The active semiconductor layer channel 216 is a distance 502 in the range of 2 to 7 micrometers from the opening 208 in the insulator. The distance is measured from the opening 208 to the closest boundary of the channel 216. The seed region 204 includes crystal grains 400 having an average first grain size 402, and the active semiconductor layer 210 includes crystal grains 222 having an average grain size 224 larger than the seed region crystal grain size 402.

FIG. 6 is a partial cross-sectional view depicting a variation in the structure of FIG. 2. A bottom gate 600 overlies the substrate 202, adjacent to the seed region 204 and underlying the active semiconductor layer 210. The bottom gate 600 has the same crystalline structure and crystallographic orientation as the seed region 204. As explained in more detail below, the bottom gate 600 and seed region 204 are formed simultaneously. A bottom gate insulator is interposed between the bottom gate 600 and the active semiconductor layer 210. As shown, the bottom gate insulator is insulator 206. Alternately however, the two insulating layers may be separate and distinct from each other.

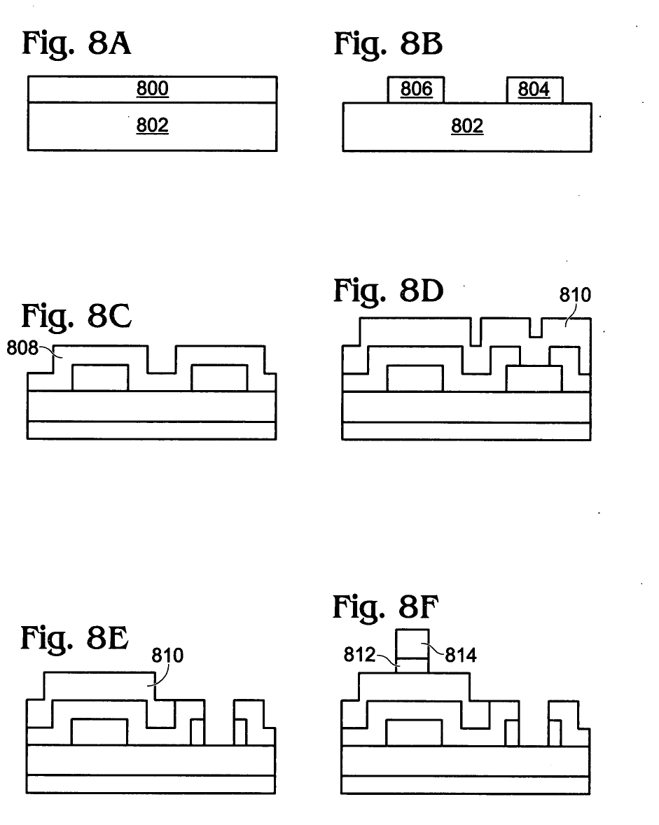

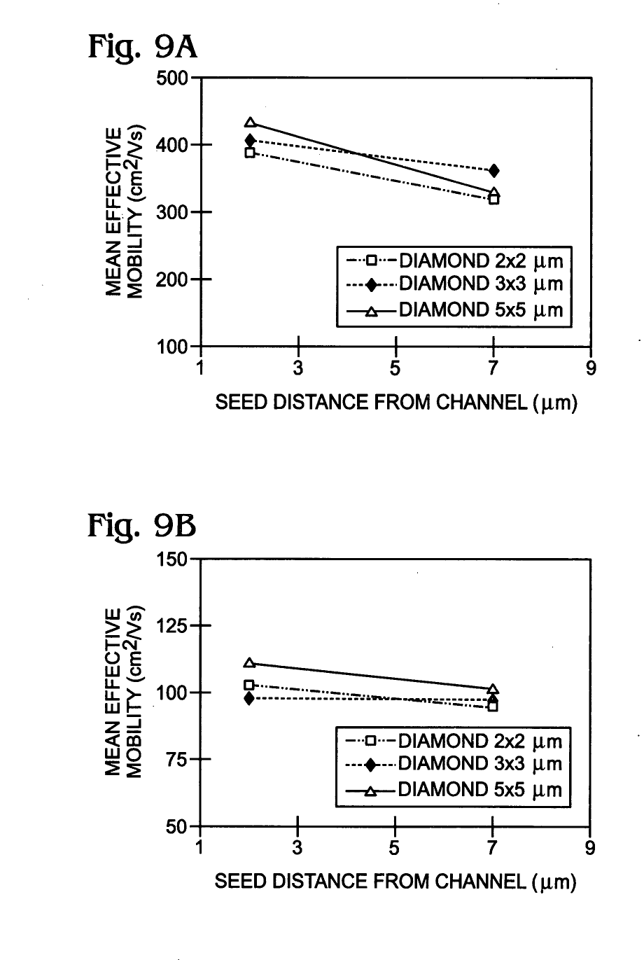

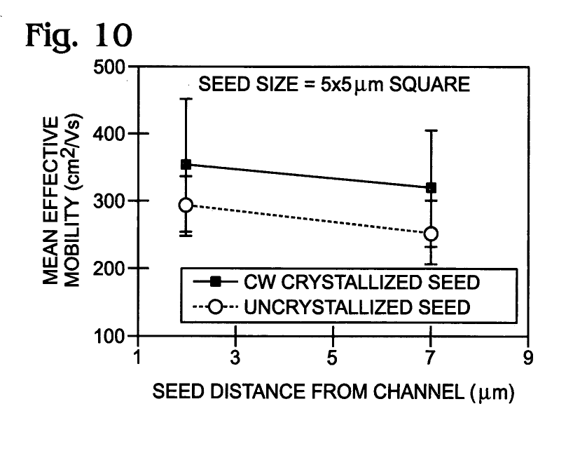

Although not specifically shown it should be understood that a seed region may be used in the fabrication of a transistor having both a top gate, as in FIG. 2, and a bottom gate, as in FIG. 6. A dual gate TFT is shown in FIG. 8F.

### Functional Description

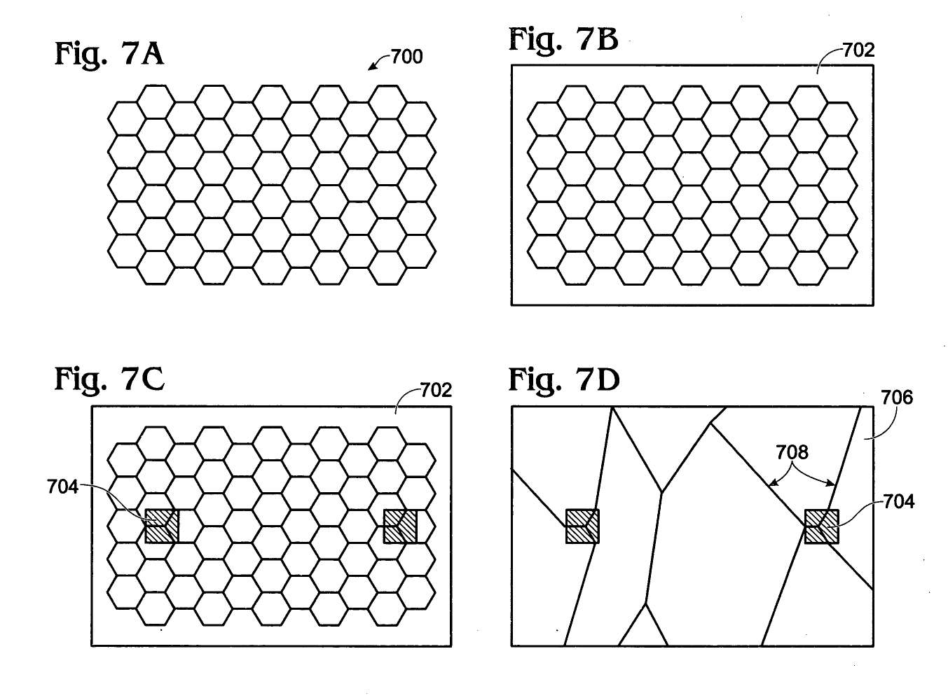

FIGS. 7A through 7D depict steps in a process of forming relatively large crystal grains with controlled boundary locations using an underlying seed region. Generally, the process designs “seeds” for the lateral crystallization of a thin-film, for example, silicon. The use of seeds is one approach for achieving control over the crystallization. That is, location-controlled grain boundaries. The location of the seeds can be selected so as to optimize the placement of grain boundaries relative to the active channel of a TFT device, so that the channel is fabricated in the crystallized film. For example, the optimum case is that the seeded crystallization causes all grain boundaries, which are detrimental to the performance of TFT devices, to form outside of the active channel. In this scenario, the active channel resides on a single-crystal island of silicon, and the associated TFT exhibits excellent performance.

FIG. 7A is a plan view of a polycrystalline first semiconductor film. The honeycomb-shaped pattern represents crystal grain boundaries. In FIG. 7B, an insulator film 702 is formed over the first semiconductor film. In FIG. 7C, openings 704 are formed in the insulator film 702. In FIG. 7D a second semiconductor film 706 has been formed over the insulator film and laser-annealed. The grain boundaries 708 are shown with respect to the openings 704.

An alternate approach to location-controlled crystallization is through patterning of the beam and careful alignment of the irradiation with the desired features on the film. The advantage of using seeds, as compared to beam patterning, is that careful alignment between the laser beam and the film is not necessary. Alignment is intrinsically achieved as a consequence of the seeds being patterned directly onto the film and/or associated layers.

Another advantage of using seeds is that the crystallographic orientation of the film can be controlled and optimized. The seed may be patterned from a layer that has previously been imparted with a specific crystallographic orientation. For example, a (100)-normal orientation may be imparted by continuous wave (CW)-laser scanning irradiation under mixed-phase-ZMR (zone-melting recrystallization) conditions. Then, that crystallographic orientation can be extended from the seed into the overlying film during the course of crystallization (lateral epitaxy).

FIGS. 8A through 8F are steps in the process of fabricating a TFT with a top gate and a bottom gate, using a location-controlled crystal seeding process. In FIG. 8A a polycrystalline semiconductor seed film 800 is formed over a substrate 802. The seed film 800 may be deposited in an amorphous form and annealed to take on a polycrystalline structure. In FIG. 8B the seed film is patterned to form a seed region 804 and a bottom gate 806. In FIG. 8C a bottom gate insulator 808 is deposited. In FIG. 8D an opening or active-to-seed via is formed, and an active semiconductor film 810 is deposited and crystallized in response to the seed region 804. In FIG. 8E the active film 810 is patterned. In FIG. 8F a top gate insulator 812 is formed with an overlying top gate electrode 814. The fabrication steps that would follow are conventional for a self-aligned top-gate TFT.

Experimental Results

Crystallization was performed using a “hybrid” scheme, which involves the nearly simultaneous irradiation of a film by both an excimer and a CO₂ laser. For optimum effect, the excimer pulse may be timed to occur right at the peak of the CO₂-laser-induced substrate heating. The CO₂ laser beam serves to heat the underlying glass or fused silica substrate, providing enhanced lateral growth before the onset of nucleation-on the order of tens of microns or more. Ideally, both the excimer beam and the CO₂ laser beam are homogenized to be spatially uniform, creating the so-called “top-hat” profile. That is, the laser beam energy is constant, within an area of 800 μm by 200 μm. Alternately, the CO₂ laser beam need not be completely homogenized, so that a Gaussian spatial distribution is exhibited. In this aspect, the CO₂ laser is restricted to the area close to the center of the beam so as to minimize the power density variation and, thus, approximate a uniform spatial distribution.

Each area of the film was irradiated a single time by both lasers in synchronization in a quasi “flood irradiation” scheme. That is, both lasers were fired in such a way that the respective pulses had a consistent and deliberate temporal relationship, for example, each excimer laser pulse began at the conclusion of a CO₂ laser pulse, with a 1:1 relationship between the pulses from the respective lasers. The beams were not patterned spatially, but rather were allowed to irradiate a particular area uniformly (i.e., “flood irradiation”). Both beams were overlapped so that they were irradiating exactly the same area. In the ideal case, the intensity of each beam would be perfectly uniform at each point within the irradiated zone (the so-called “top-hat” beam profile), although in practice this was not achieved perfectly. Nonetheless, care was taken to minimize the intensity variation of the respective beams over the “flood-irradiated” area. The area irradiated with each shot was limited by the available laser energy and the spatial uniformity of the CO₂ laser; an area of 150 μm×400 μm was typical. The entire film was irradiated sequentially by stitching together many abutting shots. However, in principle a larger beam, and fewer shots is desirable, if sufficient laser energy and beam uniformity can be achieved. Ideally, the entire substrate would be irradiated with a single shot.

During crystallization, the silicon film layer is melted completely, but the seeds are not. Resolidification begins from the locations where the molten active layer is in contact with the underlying seeds. Because of the long lateral growth that the hybrid process provides, all grain boundaries can be controlled to form outside the area intended for the active channel, provided that there are no grain boundaries present in the seed itself, which can propagate into the active channel area. Also, the orientation of the seed is extended into the active layer as it crystallizes. If the seed is a single crystal (i.e., a single grain and no grain boundaries), then the hybrid-crystallized area can ideally also be a single crystal with the same crystallographic orientation as the seed grain.

The hybrid crystallization process, utilizing a CDL (carbon dioxide laser), can easily provide lateral growth sufficiently long to create domains from the seeds that are large enough to encompass the entire active channel region. However, it has been determined that the crystallographic orientation of the film can change over long lateral growth distances. Thus, even if the seed is a single crystal with a particular crystallographic orientation (e.g., (100)-normal), the domain crystallized from the seed might contain different orientations if the lateral growth distance is extended long enough. One parameter that effects the orientation is film thickness. The orientation of the seed is preserved in the overlying annealed layer to a greater extent in thinner films than in thicker films.

Better results are to be obtained by placing the seed as close as possible to the active channel region. Given that the seed has some desirable property, such as a particular crystallographic orientation, the best chance of preserving that property in that part of the crystallized film that will become the active channel lies in minimizing the distance between the seed and the active channel.

NMOS and PMOS transistors were fabricated using square or diamond seeds of size (side) ranging from 2 to 5 μm, placed at a distance of either 2 μm or 7 μm from the TFT channel edge. The TFT channel dimensions were width/length (W/L)=8 μm/1.3 μm. The active Si film was 100 nm thick, and the gate insulator was TEOS PECVD SiO₂, 30 nm thick.

FIGS. 9A and 9B are graphs depicting the average mobility in devices made using the location-controlled crystal seeding process. In FIG. 9A the mean effective mobility of a seeded NMOS is shown. In FIG. 9B the mean effective mobility of a PMOS TFT is shown. The mobilities are cross-referenced to diamond-shaped seeds of various sizes. The TFTs have a channel W/L=8 μm/1.3 μm. As seen in the graphs, there is a decrease in effective mobility as the distance between the seed and the TFT channel increases.

FIG. 10 is a graph depicting the mean effective mobility of TFTs, contrasting a CW-crystallized seed with an amorphous seed. The seeds have a 5 μm×5 μm square shape. The TFTs have a W/L=8 μm/1.3 μm.

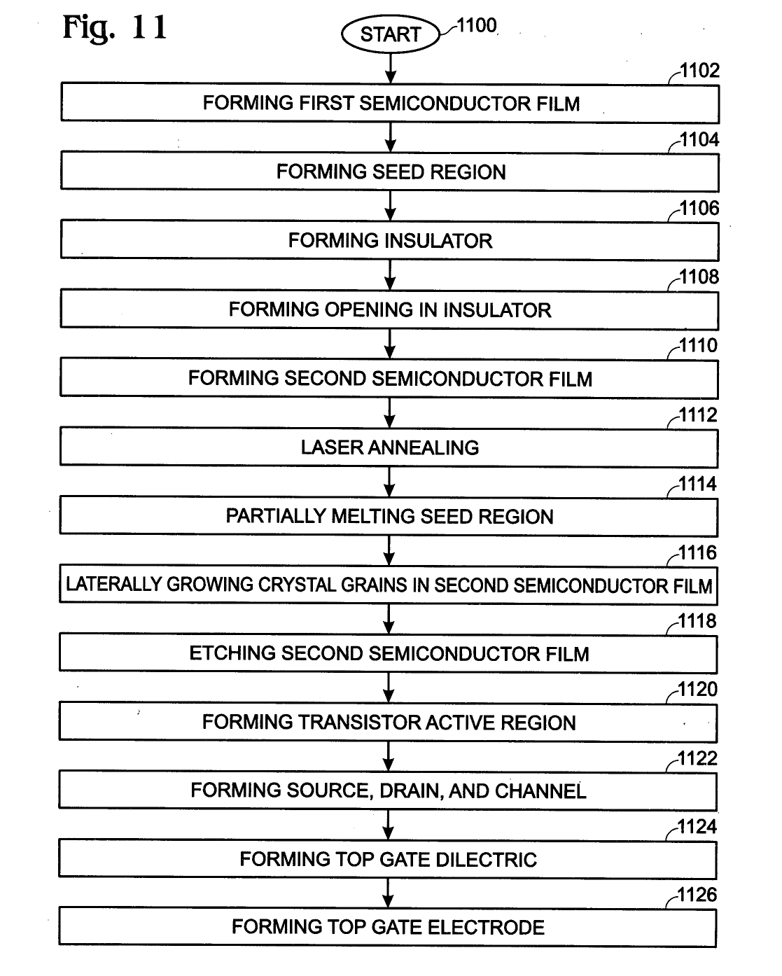

FIG. 11 is a flowchart illustrating a method for location-controlled crystallization of an active semiconductor film using a crystal seed. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 1100.

Step 1102 form a first semiconductor film overlying a substrate, having a crystallographic orientation and a crystalline structure that may be polycrystalline or single-crystal. The substrate is typically glass, plastic, quartz, fused silica, silicon, or SOI, but could be another conventional IC process substrate material. Step 1104 selectively etches the first semiconductor film, forming a seed region. Step 1106 forms an insulator overlying the seed region. Step 1108 forms an opening in the insulator, exposing the seed region. Step 1110 forms a second semiconductor film overlying the insulator layer, having an amorphous structure.

Step 1112 laser anneals the second semiconductor film. In response to the laser annealing, Step 1114 completely melts the second semiconductor film and partially melts the seed region. Step 1116 laterally grows crystal grains in the second semiconductor film having the same crystallographic orientation as the seed region. Step 1118 etches to remove the second semiconductor film overlying the seed region. As a result, Step 1120 forms a transistor active region in the remaining second semiconductor film. Step 1122 forms a source, drain, and channel in the transistor active region.

In one aspect, selectively etching the first semiconductor film in Step 1104 includes forming a bottom gate overlying the substrate, adjacent to the seed region, and forming the insulator in Step 1106 includes forming a bottom gate insulator overlying the bottom gate and the seed region. Then, forming the transistor active region in Step 1120 includes forming a transistor active region in the second semiconductor film overlying the bottom gate. Alternately, Step 1124 forms a top gate dielectric overlying the transistor active region, and Step 1126 forms a top gate (electrode) overlying the top gate dielectric. In another aspect, a dual gate transistor is formed, meaning that both a bottom gate and top gate are formed.

In one aspect, forming the first semiconductor film having the crystallographic orientation in Step 1102 includes forming the first semiconductor film with a dominant (100) orientation normal with respect to the first semiconductor film top surface. In another aspect, forming the seed region in Step 1104 includes forming crystal grains having an average grain size, and forming an opening in the insulator (Step 1108) includes forming an opening having a diameter about equal to the average grain size. Laterally growing crystal grains in the second semiconductor film (Step 1116) includes growing crystal grains having an average grain size larger than the grain size of crystals in the seed region. For example, crystal grains with a lateral growth of about 10 micrometers or greater may be formed.

In one aspect, selectively etching the first semiconductor film in Step 1104 includes forming a seed region having a shape that is a diamond or square, with sides in a range of 2 to 5 micrometers. However, the process is not necessarily limited to any particular shape or dimension. In another aspect, etching the second semiconductor film (Step 1118) and forming the transistor active region (Step 1120) includes forming a transistor channel a distance in the range of 2 to 7 micrometers from the opening in the insulator. These dimensions are typical, and may vary with changes in other process variables.

In one aspect, laser annealing the second semiconductor film in Step in Step 1112 includes irradiating a top surface of the second semiconductor film with an excimer laser in conjunction with a CO₂ laser. For example, irradiating with the CO2 and excimer lasers may include homogenizing the irradiations to be spatially uniform, or approximating a uniform spatial distribution, as described above.

An active semiconductor film structure formed from the location-controlled crystallization of a crystal seed, and an associated fabrication method have been provided. Process details, materials, and TFT structures have been used as examples to illustrate the invention. However, the invention is not limited to merely these examples. Other variations and embodiments of the invention will occur to those skilled in the art.

We claim:

1. A method for location-controlled crystallization of an active semiconductor film using a crystal seed, the method comprising:
forming a first semiconductor film overlying a substrate, having a crystallographic orientation and a crystalline structure selected from a group consisting of polycrystalline and single-crystal;
selectively etching the first semiconductor film, forming a seed region;
forming an insulator overlying the seed region;
forming an opening in the insulator, exposing the seed region;
forming a second semiconductor film overlying the insulator layer, having an amorphous structure;
laser annealing the second semiconductor film;
in response to the laser annealing, completely melting the second semiconductor film and partially melting the seed region;
laterally growing crystal grains in the second semiconductor film having the same crystallographic orientation as the seed region;
etching to remove the second semiconductor film overlying the seed region; and,
forming a transistor active region in the remaining second semiconductor film.

2. The method of claim 1 wherein selectively etching the first semiconductor film includes forming a bottom gate overlying the substrate, adjacent to the seed region;
wherein forming an insulator includes forming a bottom gate insulator overlying the bottom gate and the seed region; and,
wherein forming the transistor active region includes forming a transistor active region in the second semiconductor film overlying the bottom gate.

3. The method of claim 1 wherein forming the first semiconductor film having the crystallographic orientation includes forming the first semiconductor film with a dominant (100) orientation normal with respect to a first semiconductor film top surface.

4. The method of claim 1 wherein forming the seed region includes forming crystal grains having an average grain size; and,
wherein forming an opening in the insulator includes forming an opening having a diameter about equal to the average grain size.

5. The method of claim 1 wherein laser annealing the second semiconductor film includes irradiating a top surface of the second semiconductor film with an excimer laser in conjunction with a CO₂ laser.

6. The method of claim 5 wherein irradiating with the CO2 and excimer lasers includes homogenizing the irradiations to be spatially uniform.

7. The method of 1 wherein laterally growing crystal grains in the second semiconductor film having the same crystallographic orientation as the seed region includes growing crystal grains with a lateral growth of about 10 micrometers or greater.

8. The method of claim 1 wherein selectively etching the first semiconductor film includes forming a seed region having a shape selected from a group consisting of a diamond and a square, with sides in a range of 2 to 5 micrometers.

9. The method of claim 1 wherein etching the second semiconductor film and forming the transistor active region includes forming a transistor channel a distance in a range of 2 to 7 micrometers from the opening in the insulator.

10. The method of claim 1 further comprising:
forming a source, drain, and channel in the transistor active region.

11. The method of claim 10 further comprising:
forming a top gate dielectric overlying the transistor active region; and,
forming a top gate overlying the top gate dielectric.

12. The method of claim 1 wherein forming the first semiconductor film overlying the substrate includes forming the first semiconductor film overlying a substrate selected from a group consisting of glass, plastic, quartz, fused silica, silicon, and silicon-on-insulator (SOI).

13. The method of claim 1 wherein forming the first semiconductor film includes forming the first semiconductor film with crystal grains having an average first grain size; and,
wherein laterally growing crystal grains in the seconds semiconductor film includes growing crystal grains having an average second grain size larger than the first grain size.

14. An active semiconductor film structure formed from location-controlled crystallization of a crystal seed, the structure comprising:
a substrate;
a seed region formed overlying the substrate, having a crystallographic orientation and a crystalline structure selected from a group consisting of polycrystalline and single-crystal;
an insulator overlying the seed region;
an opening in the insulator, exposing the seed region;
an active semiconductor layer overlying the insulator layer and adjacent the opening, having the same crystallographic orientation as the seed region.

15. The structure of claim 14 further comprising:
a bottom gate overlying the substrate, adjacent to the seed region and underlying the active semiconductor layer, having the same crystalline structure and crystallographic orientation as the seed region; and,
a bottom gate insulator interposed between the bottom gate and the active semiconductor layer.

16. The structure of claim 14 wherein the seed region has a dominant (100) crystallographic orientation normal with respect to a seed region top surface.

17. The structure of claim 14 wherein the seed region includes crystal grains with an average grain size; and,
wherein the opening in the insulator has a diameter about equal to the average grain size.

18. The structure of claim 14 wherein the active semiconductor layer includes crystal grains having an average crystal grain diameter of about 10 micrometers or greater.

19. The structure of claim 14 wherein the seed region has a shape selected from a group consisting of a diamond and a square, with sides in a range of 2 to 5 micrometers.

20. The structure of claim 14 wherein the active semiconductor layer includes a transistor channel a distance in a range of 2 to 7 micrometers from the opening in the insulator.

21. The structure of claim 14 further comprising:
a source, drain, and channel in the active semiconductor layer.

22. The structure of claim 21 further comprising:
a top gate dielectric overlying the active semiconductor layer; and,
a top gate overlying the top gate dielectric.

23. The structure of claim 14 wherein the substrate is a material selected from a group consisting of glass, plastic, quartz, fused silica, silicon, and silicon-on-insulator (SOI).

24. The structure of claim 14 wherein the seed region includes crystal grains having an average first grain size; and,
wherein the active semiconductor layer includes crystal grains having an average second grain size larger than the first grain size.
